(19) United States
(12) Patent Application Publication
(10) Pub. No.: US 2003/0098178 A1
(43) Pub. Date: May 29, 2003

(54) Printed circuit board having test points formed on sides thereof

(75) Inventors: Toshiyuki Shibuya, Tokyo (JP); Kazuya Ozaki, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/303,748

(22) Filed: Nov. 26, 2002

(30) Foreign Application Priority Data
Nov. 27, 2001 (JP) 2001-360810

(51) Int. Cl. H05K 1/11

(52) U.S. Cl. 174/261

(57) ABSTRACT

A plurality of test points are formed on lengthwise and/or widthwise side portions of the substrate of a printed circuit board. Each test point can be formed by cutting away a semicircular part from the side portion of the substrate. Conductive leads are formed on the substrate so as to originate from a component mounting area (on which an IC will be mounted) and reach each of the test points. The test points and the conductive leads are electrically connected together by a plating process. The printed circuit board having test points formed on the side portions thereof causes various limitations and constraints on the placement and arrangement of the test points to be eased and relaxed.

### BACKGROUND OF THE INVENTION

1. Field Of the Invention

The present invention relates to a printed circuit board that is provided with terminals to be used for the testing thereof.

2. Description of the Related Art

In this disclosure, the term “test points” is defined as terminals on a printed circuit board which are to be electrically connected to a testing system.

The operation test or inspection of a printed circuit hoard is generally carried out by monitoring necessary signals obtained via a plurality of test points that are provided, for example, on specific parts of the surface of the circuit board.

In recent years, however, technologies for manufacturing printed circuit boards and mounting a variety of parts on the printed circuit boards are progressing rapidly and the number of parts to be mounted on a circuit board of electronic equipment is more and more increasing for realizing high versatility. As a result, vacant space or free area on the surface of the circuit board is getting smaller and smaller and thereby it is becoming very difficult to secure spaces for the test points on the surface of the circuit board.

In such circumstances, some techniques for resolving the above problem have been proposed. In Japanese Patent Application Laid-Open No.HEI6-11546, the operation test of the printed circuit board is carried out using the test points which are not formed on the surface thereof but on a disposable board section thereof. When the circuit board passes the operation test, the disposable board section is removed from the printed circuit board before the printed circuit board is conveyed to the following assembly stage.

In Japanese Patent Application Laid-Open No.HEI10-41329, the test points are not provided on the surface of the printed circuit board but on the top surface of the package of an IC (Intergrated Circuit), which is mounted on the surface of the printed circuit board.

However, the printed circuit boards as described above involve the following problems or drawbacks.

First, in Japanese Patent Application Laid-Open No.HEI6-11546, the disposable board section is removed from the printed circuit board when the printed circuit board has passed the operation test and then the printed circuit board having no test points is transported to the assembly stage. Therefore, it is impossible to conduct the operation test after the printed circuit board (from which the disposable board section has been removed) has been conveyed to the assembly process. For example, when malfunction or failure is found after the shipment of the electronic equipment, there is no way to conduct the operation test for re-inspection or the like.

In Japanese Patent Application Laid-Open No.HEI10-41329, the test points are formed on the surface of the package of an IC. Therefore, it is impossible to provide the IC with a shielding metal cover. In other words, once the shielding metal cover is attached to the IC, the test points are hidden by the shielding metal cover and cannot be used anymore. Incidentally, the mounting of the shielding metal cover is generally carried out concurrently with the mounting of the IC on the printed circuit board in the same process, therefore, the test points get hidden before the inspection.

### SUMMARY OF THE INVENTION

It is therefore an object of the present invention to provide a printed circuit board allowing various limitations and restrictions in placement and arrangement of test points on the printed circuit board to be eased and relaxed.

In accordance with a first aspect of the present invention, there is provided a printed circuit board including: a substrate having a major surface and a back surface, a plurality of test points which are formed on at least one side of the substrate; a component mounting area provided on the major surface of the substrate; and a plurality of conductive leads which are formed on the major surface of the substrate and extend from predetermined positions of the component mounting area to respective ones of the test points, wherein each of the conductive leads is electrically connected to a corresponding one of the test points.

The test points may be formed on at least one opposed pair of sides in a lengthwise direction and/or a width direction of the substrate.

Each of the test points may be formed in a recess on said at least one side of the substrate, wherein the recess is shaped like a semicircular cylinder and extends from the major surface to the back surface of the substrate.

Each of the test points may be formed in a recess on said at least one side of the substrate, wherein the recess is shaped like a triangular prism and extends from the major surface to the back surface of the substrate.

Each of the test points may be formed in a recess on said at least one side of the substrate, wherein the recess is shaped like a quadrangular prism and extends from the major surface to the back surface of the substrate.

Each of the test points may be formed in a recess on said at least one side of the substrate, wherein the recess is shaped like a semicircular cylinder and extends from the major surface to some midpoint between the major surface and the back surface of the substrate.

Each of the test points may be formed in a recess on said at least one side of the substrate, wherein the recess is shaped like a triangular prism and extends from the major surface to some midpoint between the major surface and the back surface of the substrate.

Each of the test points may be formed in a recess on said at least one side of the substrate, wherein the recess is shaped like a quadrangular prism and extends from the major surface to some midpoint between the major surface and the back surface of the substrate.

Each of the test points may include a conductor formed on at least one side edge of the major surface of the substrate.

The test points may be connected to respective ones of the conductive leads by plating the test points.

In accordance with a second aspect of the present invention, there is provided a method for manufacturing a printed circuit board having a plurality of test points, including the steps of: a) preparing a substrate having a major surface and a back surface, wherein a component mounting area is previously determined on the major surface; b) forming a plurality of recesses at predetermined positions on at least one side of the substrate; c) forming a plurality of conductive leads on the major surface of the substrate and extending from predetermined positions of the component mounting area to respective ones of the test points; and d) coating each of the recesses with an electrically conductive material to form the test points which are electrically connected to the conductive leads, respectively.

Preferably, the step b) is performed concurrently with a through-hole forming process in which at least one through hole is formed in the substrate; and the step d) is performed concurrently with a plating process of the through-hole forming process so that each of the recesses is plated with the electrically conductive material.

In the printed circuit board in accordance with the present invention, a plurality of test points are formed on side portions of the substrate of a printed circuit board. Conductive leads are formed on the substrate so as to originate from a component mounting area (on which an IC will be mounted) and reach each of the test points. The test points and the conductive leads are electrically connected together by a plating process which is carried out for the test points. The operation test of the printed circuit board can be conducted by monitoring changes of signals which are obtained from the test points. By the printed circuit board according to the present invention, various limitations and constraints on the placement and arrangement of the test points on the printed circuit board can be eased and relaxed.

### BRIEF DESCRIPTION OF THE DRAWINGS

The objects and features of the present invention will become more apparent from the consideration of the following detailed description taken in conjunction with the accompanying drawings, in which:

FIG. 1 is a plan view showing a printed circuit board in accordance with a first embodiment of the present invention;

FIG. 2 is a perspective view showing test points of the printed circuit board of FIG. 1;

FIG. 3 is a perspective view showing test points of a printed circuit board in accordance with a second embodiment of the present invention;

FIG. 4 is a perspective view showing test points of a printed circuit board in accordance with a third embodiment of the present invention;

FIG. 5 is a perspective view showing test points of a printed circuit board in accordance with a fourth embodiment of the present invention;

FIG. 6 is a perspective view showing test points of a printed circuit board in accordance with a fifth embodiment of the present invention;

FIG. 7 is a perspective view showing test points of a printed circuit board in accordance with a sixth embodiment of the present invention; and

FIG. 8 is a perspective view showing test points of a printed circuit board in accordance with a seventh embodiment of the present invention.

### DESCRIPTION OF THE PREFERRED EMBODIMENTS

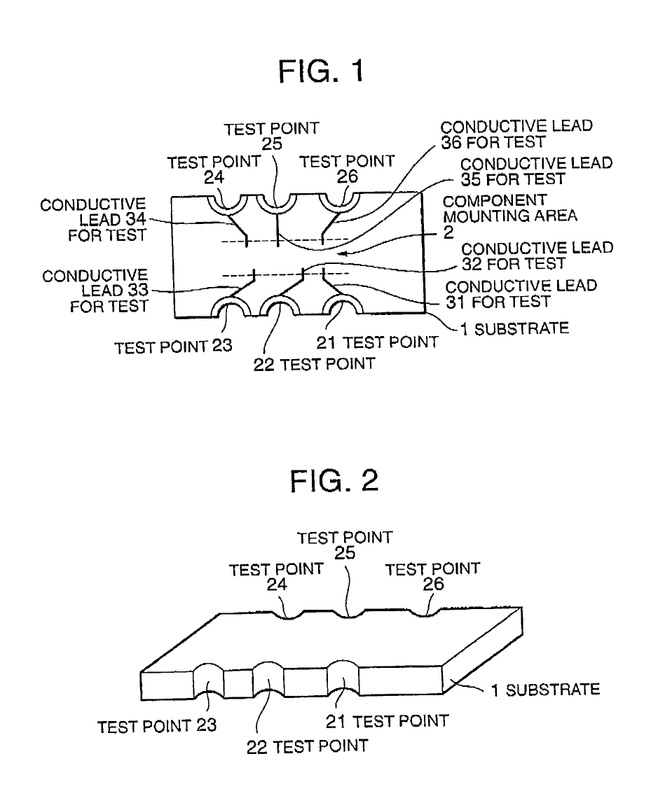

Referring to FIG. 1, on the major surface of an insulating substrate 1 of the printed circuit board, a component mounting area 2 is reserved, for example, in the middle of the major surface as an area on which an unshown IC (Integrated Circuit) will be mounted. On lengthwise sidle portions of the substrate 1, a plurality of test points 21-23 and 24-26 are provided. As shown in FIG. 2, the respective test points 21-26 are formed by cutting away semi-cylindrical parts from the side portions of the substrate 1 to form semicircular recesses. The formation of the test points 21-26 can be carried out concurrently with the formation of through-holes in the substrate 1.

More specifically, the inner surface of each semi-cylindrical recess and the edge portions on the major surface around the semi-cylindrical recess are plated with an electrically conductive material which is the same as used in the through-hole formation process. The plating for the test points 21-26 is carried out concurrently with a plating process for the through holes. The plating causes the semi-cylindrical recesses to be test signal terminals functioning as the test points 21-26. Accordingly, the respective test points 21-26 can be electrically connected to the test pins of a measuring instrument or tester.

On the major surface of the substrate 1, a plurality of conductive leads 31-36 dedicated for test are formed each extending from predetermined positions in the component mounting area 2 to the test points 21-26. Each of the conductive leads 31-36 is electrically connected to a corresponding one of the test points 21-26 in the aforementioned plating process. In other words, the respective conductive leads 31-36 connect the leads of an IC mounted on the component mounting area 2 to the test points 21-26, allowing the tester to monitor necessary signals from the IC though the test points 21-26.

A method for manufacturing a printed circuit board composed as above will be described hereinafter. In the process for forming through-holes in the substrate 1, a preset number of test points 21-26 are formed at predetermined positions on the side portions of the substrate 1 by removing predetermined parts from the side portions of the substrate 1. Subsequently, from the component mounting area 2 on which the IC will be mounted, the respective conductive leads 31-36 are formed on the substrate 1 so as to reach the tenet points 21-26. Thereafter, in the plating process for the through holes, the inner surfaces of the semi-cylindrical recesses each corresponding to the test points 21-26 and the edge portions on the major surface around the semicircular recesses are plated with the same conductive material and thereby the printed circuit board having the composition described above is completed.

The operation test of such a printed circuit board can be carried out as follows. First, the substrate 1 having the IC mounted thereon is fixed securely to a fixture etc. so as not to move. Then, test pins which have been connected with a measuring instrument (not shown in the figure) come into contact with respective ones of the test points 21-26, and changes of signals on the test points 21-26 are monitored by the measuring instrument to determine whether the printed circuit board normally operates.

As described above, in the printed circuit board in accordance with the first embodiment of the present invention, the test points 21-26 are formed on the sides of the substrate 1. The conductive leads 31-36 are formed on the substrate 1, each extending from the component mounting area 2 (on which the IC will be mounted) to the test points 21-26. The test points 21-26 and the (conductive leads 31-36 are electrically connected together by the plating process which is carried out for the test points 21-26. The operation test of the printed circuit board can be conducted by monitoring the changes of signals which arc obtained from the test points 21-26. Such composition of the printed circuit board permits easing of various limitations and constraints on the placement and arrangement of the test points on the substrate 1.

Specifically, the test points 21-26 are formed on the sides of the substrate 1 that are away from the mounting areas of components. Therefore, the test points 21-26 can certainly be formed in the substrate 1 even if available space on the major surface of the substrate 1 becomes smaller due to the increasing number of parts caused by the electronic equipment's versatility along with the progress of technologies for manufacturing printed circuit hazards and mounting a variety of parts on the printed circuit boards.

Thanks to the test points 21-26 formed on the sides of the substrate 1, the operation test of the printed circuit board can be carried out even after the circuit board has been transported to the assembly stage, differently from the conventional printed circuit board in which the aforementioned disposable board having the test points is removed from the circuit board before the assembling of the electronic equipment. Therefore, even when malfunction or failure is found out after the shipment of the electronic equipment for example, an extra operation test can be carried out for re-inspection etc.

Further, in the printed circuit board of this embodiment having the test points 21-26 on the sides of the substrate 1, the problem with the conventional printed circuit board having the test points on the surface of the package of an IC: the impossibility of providing a shielding metal cover to the IC, can be resolved.

Furthermore, by the arrangement of the test points 21-26 on the sides of the substrate 1 apart from the component mounting area, the flexibility of pattern designing on the component mounting surface of the substrate 1 can be increased considerably and the pattern designing of the printed circuit board can be carried out more efficiently, thereby the improvement of characteristics can be achieved more easily and effectively.

The present invention is not limited to the placement of test points such that they are formed on the sides of the substrate 1 in the lengthwise direction as shown in FIGS. 1 and 2.

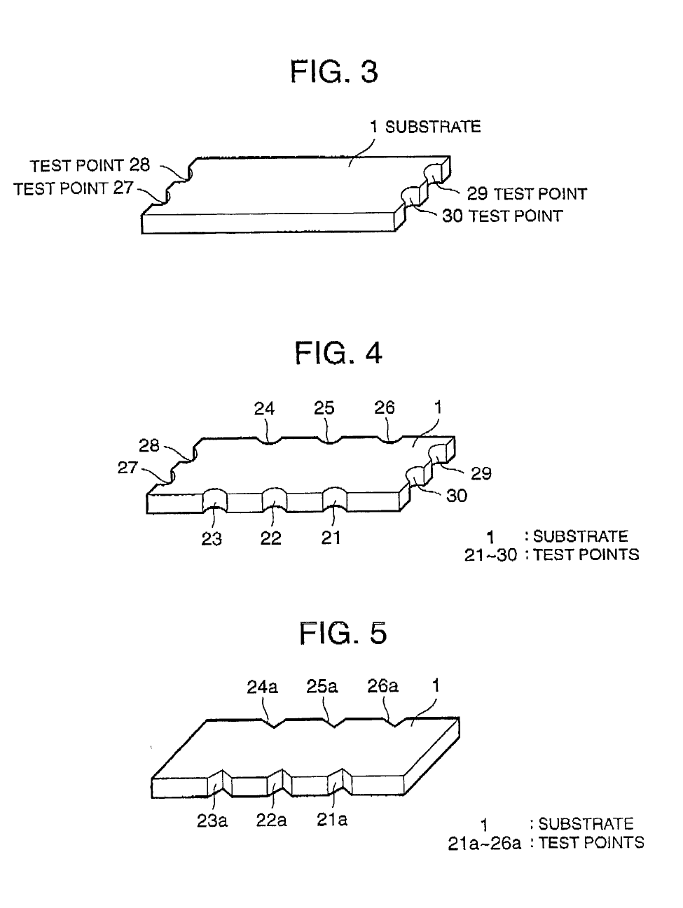

As shown in FIG. 3, it is also possible to form the test points 27-30 on sides in the width direction (cross direction).

As shown in FIG. 4, it is further possible to form the test points 21-30 on the sides in both lengthwise direction and widthwise direction.

The present invention is not limited to the semi-cylindrical shape of test points as shown in FIGS. 1-4.

As shown in FIG. 5, a test point can also be shaped like a triangular prism. A plurality of test points 21a-26a are formed in the shape of a triangular prism on the sides of the substrate 1 in the lengthwise direction. As described before, the test points each having the shape of a triangular prism may be formed on the sides in both lengthwise direction and widthwise direction.

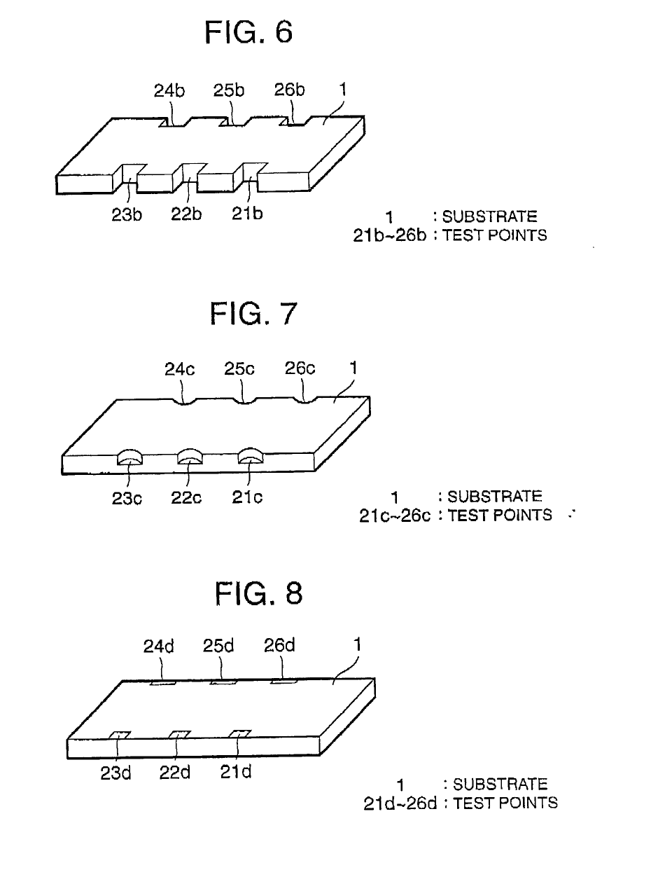

As shown in FIG. 6, a test point can also be shaped like a quadrangular prism. A plurality of test points 21b-26b are formed in the shape of a quadrangular prism on the sides of the substrate 1 in the lengthwise direction. As described before, the test points each having the shape of a quadrangular prism may be formed on the sides in both lengthwise direction and widthwise direction.

In the above embodiments, the test points were formed by cutting away parts of the side portions totally from the major surface to the back surface of the substrate 1 as in the case of forming through holes. The present invention is not limited to such a structure.

As shown in FIG. 7, it is also possible to form the test points 21c-26c by removing parts of the side portions from the major surface to some midpoint between the major surface and the back of the substrate 1. In other words, the test points may be formed by cutting away only edge portions of the major surface side of the substrate 1. Each test point may be shaped like a semicircular, a triangular prism, or a quadrangular prism as described above.

As shown in FIG. 8, it is also possible to form test points 21d-26d by carrying out plating only on the edge portions of the major surface side of the substrate 1.

As set forth hereinabove, in the printed circuit boards in accordance with the present invention, a plurality of test points are formed on the side portions of the printed circuit board. The conductive leads are formed on the major surface of the substrate so as to extend from the component mounting area (on which the IC will be mounted) to respective ones of the test points. The test points and the conductive leads are electrically connected together by the plating process which is carried out for the test points. The operation test of the printed circuit board can be conducted by monitoring changes of signals which are obtained from the test points. By the printed circuit boards according to the present invention, various limitations and constraints on the placement and arrangement of the test points on the printed circuit board or its substrate can be eased and relaxed.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A printed circuit board comprising:
a substrate having a major surface and a back surface;
a plurality of test points which are formed on at least one side of the substrate;
a component mounting area provided on the major surface of the substrate; and
a plurality of conductive leads which are formed on the major surface of the substrate and extend from predetermined positions of the component mounting area to respective ones of the test points, wherein each of the conductive leads is electrically connected to a corresponding one of the test points.

2. The printed circuit board as claimed in claim 1, wherein the test points are formed on at least one opposed pair of sides in a lengthwise direction and/or a width direction of the substrate.

3. The printed circuit board as claimed in claim 1, wherein each of the test points is formed in a recess on said at least one side of the substrate, wherein the recess is shaped like a semicircular cylinder and extends from the major surface to the back surface of the substrate.

4. The printed circuit board as claimed in claim 1, wherein each of the test points is formed in a recess on said at least one side of the substrate, wherein the recess is shaped like a triangular prism and extends from the major surface to the back surface of the substrate.

5. The printed circuit board as claimed in claim 1, wherein each of the test points is formed in a recess on said at least one side of the substrate, wherein the recess is shaped like a quadrangular prism and extends from the major surface to the back surface of the substrate.

6. The printed circuit board as claimed in claim 1, wherein each of the test points is formed in a recess on said at least one side of the substrate, wherein the recess is shaped like a semicircular cylinder and extends from the major surface to some midpoint between the major surface and the back surface of the substrate.

7. The printed circuit board as claimed in claim 1, wherein each of the test points is formed in a recess on said at least one side of the substrate, wherein the recess is shaped like triangular prism and extends from the major surface to some midpoint between the major surface and the back surface of the substrate.

8. The printed circuit board as claimed in claim 1, wherein each of the test points is formed in a recess on said at least one side of the substrate, wherein the recess is shaped like a quadrangular prism and extends from the major surface to some midpoint between the major surface and the back surface of the substrate.

9. The printed circuit board as claimed in claim 1, wherein each of the test points comprises a conductor formed on at least one side edge of the major surface of the substrate.

10. The printed circuit board as claimed in claim 1, wherein the test points is connected to respective ones of the conductive leads by plating the test points.

11. A method for manufacturing a printed circuit board having a plurality of test points, comprising the steps of:
a) preparing a substrate having a major surface and a back surface, wherein a component mounting area is previously determined on the major surface;
b) forming a plurality of recesses at predetermined positions on at least one side of the substrate;
c) forming a plurality of conductive leads on the major surface of the substrate and extending from predetermined positions of the component mounting area to respective ones of the test points; and
d) coating each of the recesses with an electrically conductive material to form the test points which ire electrically connected to the conductive leads, respectively.

12. The method as claimed in claim 11, wherein
the step b) is performed concurrently with a through-hole forming process in which at least one through hole is formed in the substrate; and
the step d) is performed concurrently with a plating process of the through-hole forming process so that each of the recesses is plated with the electrically conductive material.
